(19) United States
(12) Patent Application Publication
(10) Pub. No.: US 2021/0384251 A1
(43) Pub. Date: Dec. 9, 2021

(54) IMAGE SENSING DEVICE

(71) Applicant: SK hynix Inc., Icheon-si (KR)

(72) Inventor: Soon Yeol PARK, Icheon-si (KR)

(21) Appl. No.: 17/183,077

(22) Filed: Feb. 23, 2021

(30) Foreign Application Priority Data
Jun. 4, 2020 (KR) 10-2020-0067504

(51) Int. Cl. H01L 27/148; H01L 27/146

(52) U.S. Cl. CPC H01L 27/14831; H01L 27/14636; H01L 27/14603; H01L 27/14612

(57) ABSTRACT

An image sensing device includes at least one photoelectric conversion element configured to generate photocharges by performing photoelectric conversion of incident light, a floating diffusion region adjacent to the at least one photoelectric conversion element and configured to receive and store the photocharges, at least one transfer transistor electrically coupled to the at least one photoelectric conversion element and the floating diffusion region and configured to transmit the photocharges generated by the photoelectric conversion element to the floating diffusion region in response to a transmission signal, and at least one boosting conductive material configured to receive a boosting voltage to boost the floating diffusion region and disposed in a region (1) that is vertically apart by a predetermined distance from the floating diffusion region and (2) vertically non-overlapping with the at least one transfer transistor.

### CROSS-REFERENCE TO RELATED APPLICATION

This patent document claims the priority and benefits of Korean patent application No. 10-2020-0067504, filed on Jun. 4, 2020, which is incorporated by reference in its entirety as part of the disclosure of this patent document.

### TECHNICAL FIELD

The technology and implementations disclosed in this patent document generally relate to an image sensing device.

### BACKGROUND

An image sensor is a device (or an element) for converting an optical image into electrical signals using a semiconductor material that reacts to light. With the recent development of computer industries and communication industries, demand for higher-integration and higher-performance image sensors has been increasing in various devices, for example, digital cameras, camcorders, personal communication systems (PCSs), video game consoles, surveillance cameras, medical micro-cameras, robots, etc.

### SUMMARY

Various embodiments of the disclosed technology relate to an image sensing device for boosting a floating diffusion region while less affecting other peripheral elements contiguous or adjacent to the floating diffusion region.

In one aspect, an image sensing device is provided to include at least one photoelectric conversion element configured to generate photocharges by performing photoelectric conversion of incident light; a floating diffusion (FD) region configured to store the photocharges; at least one transfer transistor configured to transmit the photocharges generated by the photoelectric conversion element to the floating diffusion (FD) region in response to a transmission signal; and at least one boosting conductive material disposed at an upper portion of the floating diffusion (FD) region while being spaced apart from the floating diffusion (FD) region by a predetermined distance, and configured to boost the floating diffusion (FD) region, wherein the at least one boosting conductive material is disposed not to overlap with the at least one transfer transistor.

In another aspect, an image sensing device is provided to include at least one photoelectric conversion element configured to generate photocharges by performing photoelectric conversion of incident light, a floating diffusion region adjacent to the at least one photoelectric conversion element and configured to receive and store the photo charges, at least one transfer transistor electrically coupled to the at least one photoelectric conversion element and the floating diffusion region and configured to transmit the photocharges generated by the photoelectric conversion element to the floating diffusion region in response to a transmission signal, and at least one boosting conductive material configured to receive a boosting voltage to boost the floating diffusion region and disposed in a region (1) that is vertically apart by a predetermined distance from the floating diffusion region and (2) vertically non-overlapping with the at least one transfer transistor.

In accordance with another embodiment of the disclosed technology, an image sensing device may include a pixel array of unit pixel groups, each unit pixel group including a plurality of unit pixels that generates an electrical signal in response to incident light through a photoelectric conversion of the incident light and shares a single floating diffusion region. Each of the unit pixel group may include a plurality of photoelectric conversion elements configured to generate photocharges by performing the photoelectric conversion of the incident light, a plurality of transfer transistors configured to transmit the photocharges generated by the corresponding photoelectric conversion element to the floating diffusion region in response to a transmission signal, and at least one boosting conductive material spaced apart from the floating diffusion region by a predetermined distance, and configured to vertically overlap with the floating diffusion region without overlapping with the plurality of transfer transistors.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a boosting structure formed in a unit pixel group based on some implementations of the disclosed technology.

FIG. 3 is a cross-sectional view illustrating an example of a pixel array taken along the line A-A′ shown in FIG. 2 based on some implementations of the disclosed technology.

FIG. 4 is a cross-sectional view illustrating an example of the pixel array taken along the line B-B′ shown in FIG. 2 based on some implementations of the disclosed technology.

### DETAILED DESCRIPTION

This patent document provides implementations and examples of an image sensing device and the disclosed features may be implemented to substantially address one or more issues due to limitations and disadvantages of various image sensing devices. Some implementations of the disclosed technology suggest designs of an image sensing device that can boost a floating diffusion (FD) region while less affecting other peripheral elements contiguous or adjacent to the floating diffusion (FD) region. The disclosed technology provides various implementations of an image sensing device which can enable a boosting voltage generated by boosting a floating diffusion (FD) region to minimally affect operations of other peripheral elements, such that capacitance of a boosting capacitor can be easily adjusted.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

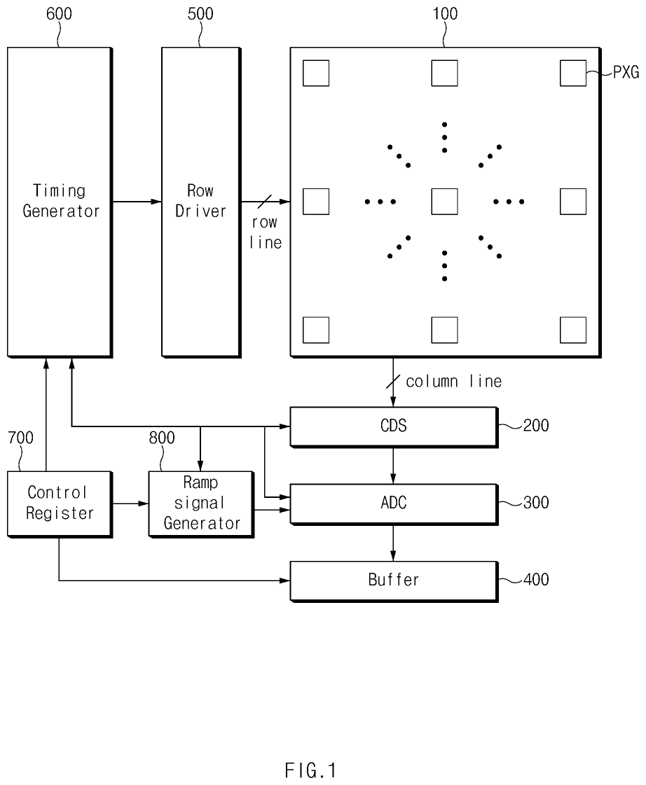

FIG. 1 is a block diagram illustrating an example of an image sensing device based on some implementations of the disclosed technology.

Referring to FIG. 1, the image sensing device may include a pixel array 100, a correlated double sampler (CDS) 200, an analog-to-digital converter (ADC) 300, a buffer 400, a row driver 500, a timing generator 600, a control register 700, and a ramp signal generator 800.

The pixel array 100 may include a plurality of unit pixel groups (PXGs) consecutively arranged in a two-dimensional (2D) structure in which the unit pixel groups (PXGs) are arranged in an X-axis direction and a Y-axis direction perpendicular to the X-axis direction. Each unit pixel group (PXG) may enable the plurality of unit pixels to share a single floating diffusion region. For example, the unit pixel group (PXG) may include four unit pixels that are spaced apart from each other by a predetermined distance while surrounding the floating diffusion region with respect to the single floating diffusion region disposed at a center part. Each unit pixel may generate a pixel signal corresponding to incident light through photoelectric conversion of the incident light received from the outside, and may output the pixel signal to the correlated double sampler (CDS) 200 through column line. Each unit pixel may include a photoelectric conversion element configured to generate photocharges by performing photoelectric conversion of incident light, and a transfer transistor configured to transmit the photocharges generated by the photoelectric conversion element to a floating diffusion region based on a transmission signal. Each unit pixel group (PXG) may include a boosting capacitor to boost the floating diffusion region. The boosting capacitor may include a boosting contact formed over the floating diffusion region. A detailed description of the boosting contact structure will be given at a later time.

The correlated double sampler (CDS) 200 may sample and hold pixel signals received from the unit pixels of the pixel array 100.

For example, the correlated double sampler (CDS) 200 may perform sampling of a reference voltage level and a voltage level of the received pixel signal in response to a clock signal received from the timing generator 600, and may transmit an analog signal corresponding to a difference between the reference voltage level and the voltage level of the received pixel signal to the analog-to-digital converter (ADC) 300.

The analog-to-digital converter (ADC) 300 may convert an analog signal received from the correlated double sampler (CDS) 200 into a digital signal in response to a clock signal received from the timing generator 600 and a ramp signal received from the ramp signal generator 800.

The buffer 400 may latch each of the digital signals received from the analog-to-digital converter (ADC) 300, may sense and amplify each of the digital signals, and may output each of the amplified digital signals.

The row driver 500 may be coupled or connected to drive the pixel array 100 in response to an output signal of the timing generator 600.

The timing generator 600 may generate a timing signal to control the row driver 500, the correlated double sampler (CDS) 200, the analog-to-digital converter (ADC) 300, and the ramp signal generator 800.

The control register 700 may generate control signals to control the ramp signal generator 800, the timing generator 600, and the buffer 400.

The ramp signal generator 800 may generate a ramp signal in response to a control signal of the control register 700 and a timing signal received from the timing generator 600, and may output the ramp signal to the analog-to-digital converter (ADC) 300. The signal output from the analog-to-digital converter (ADC) 300 to buffer 400 may be controlled by the ramp signal.

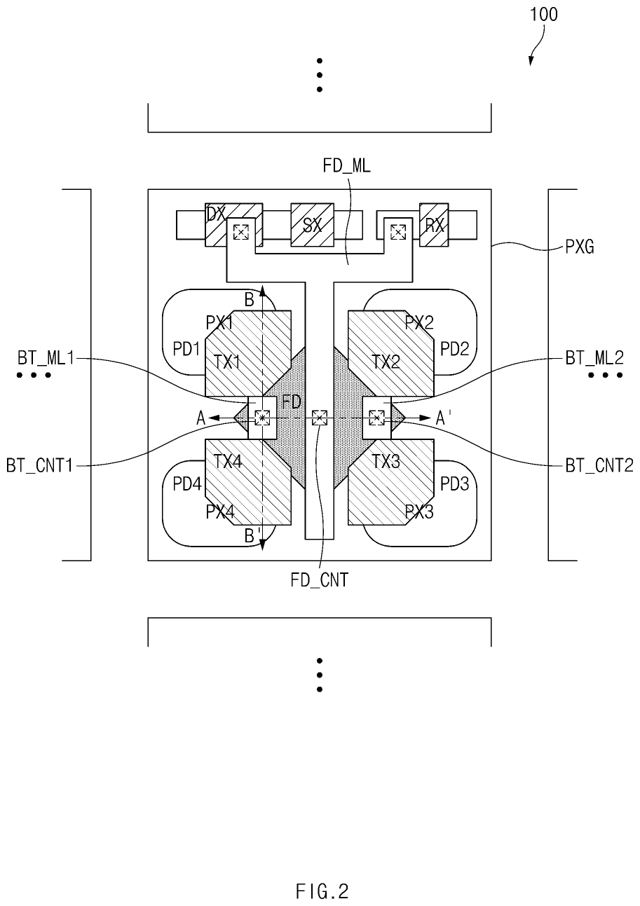

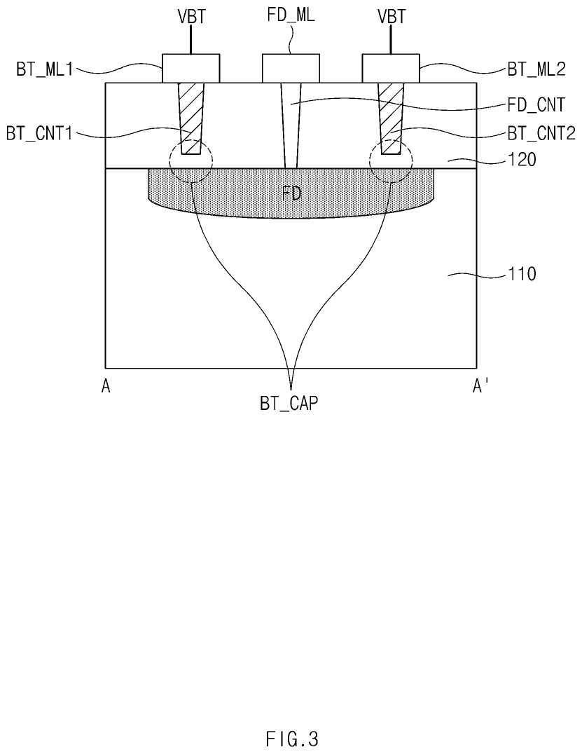

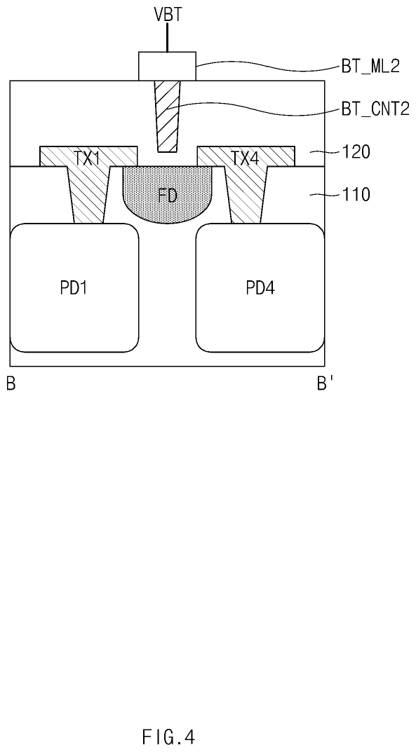

FIG. 2 is a schematic diagram illustrating an example of a boosting structure formed in the unit pixel group based on some implementations of the disclosed technology. FIG. 3 is a cross-sectional view illustrating an example of the pixel array taken along the line A-A′ shown in FIG. 2 based on some implementations of the disclosed technology. FIG. 4 is a cross-sectional view illustrating an example of the pixel array taken along the line B-B′ shown in FIG. 2 based on some implementations of the disclosed technology.

Referring to FIGS. 2 to 4, the pixel array 100 may include a plurality of unit pixel groups (PXGs) consecutively arranged in an X-axis direction and a Y-axis direction. Each unit pixel group (PXG) may include a plurality of unit pixels PX1˜PX4, each of which generates an electrical signal corresponding to incident light through photoelectric conversion of the incident light received from the outside. In this case, the unit pixels PX1˜PX4 may share a single floating diffusion region FD. For example, each unit pixel group (PXG) may include four unit pixels PX1˜PX4 that are arranged contiguous or adjacent to each other in a (2×2) structure and surround the one shared floating diffusion region FD. In more detail, the four unit pixels PX1˜PX4 surrounding the single floating diffusion region FD may be arranged in a (2×2) structure while being contiguous or adjacent to each other.

The unit pixels PX1˜PX4 may respectively include photoelectric conversion elements PD1˜PD4 for generating photocharges through photoelectric conversion of incident light, and may respectively include transfer transistors TX1˜TX4 for transmitting photocharges generated by the photoelectric conversion elements PD1˜PD4 to the floating diffusion region FD in response to a transmission signal. In more detail, the unit pixel PX1 may include the photoelectric conversion element PD1 and the transfer transistor TX1, the unit pixel PX2 may include the photoelectric conversion element PD2 and the transfer transistor TX2, the unit pixel PX3 may include the photoelectric conversion element PD3 and the transfer transistor TX3, and the unit pixel PX4 may include the photoelectric conversion element PD4 and the transfer transistor TX4. The photoelectric conversion elements PD1˜PD4 may be disposed in the substrate 110 of the unit pixels PX1˜PX4, and the floating diffusion region FD may be formed at an upper portion of the substrate 110. For example, the substrate 110 may include a first surface (i.e., a bottom surface in FIG. 3 or 4) upon which light is incident, and a second surface (i.e., a top surface in FIG. 3 or 4) facing or opposite to the first surface. The floating diffusion region FD may be formed at an upper portion of the substrate 110. An insulation layer 120 may be formed over the substrate 110.

The floating diffusion region FD may be electrically coupled to a conductive line FD_ML through a floating diffusion contact FD_CNT. The conductive line FD_ML may be coupled to one terminal (i.e., a source/drain terminal) of the reset transistor RX and a gate of the source follower transistor DX of the corresponding unit pixel group (PXG).

A plurality of boosting contacts BT_CNT1 and BT_CNT2 may be formed over the floating diffusion region FD while being spaced apart from the floating diffusion region FD by a predetermined distance. For example, the boosting contacts BT_CNT1 and BT_CNT2 may be formed over the floating diffusion region FD in a manner that the boosting contacts BT_CNT1 and BT_CNT2 can vertically overlap with the floating diffusion region FD. The insulation layer 120 (having a predetermined thickness) may be formed between the floating diffusion region FD and the boosting contacts BT_CNT1 and BT_CNT2. In some implementations, the insulation layer 120 may extend such that the boosting contacts BT_CNT1 and BT_CNT2 are formed in the insulation layer 120. The boosting contact BT_CNT1 may be coupled to a conductive line BT_ML1, and the boosting contact BT_CNT2 may be coupled to a conductive line BT_ML2. The conductive line BT_ML1 and the conductive line BT_ML2 may be coupled to a boosting voltage node VBT through which the boosting voltage is received. The conductive lines BT_ML1 and BT_ML2 may be formed at the same metal layer as the conductive line FD_ML. For example, the conductive lines BT_ML1, BT_ML2, and FD_ML may be formed at a first metal layer M1.

The boosting contacts BT_CNT1 and BT_CNT2 may be disposed between the transfer transistors TX1˜TX4. In more detail, the boosting contact BT_CNT1 may be disposed between the transfer transistors TX1 and TX4, and the boosting contact BT_CNT2 may be disposed between the transfer transistors TX2 and TX3. For example, the boosting contacts BT_CNT1 and BT_CNT2 may be symmetrically disposed at both sides of the floating diffusion contact FD_CNT. The boosting contact BT_CNT1 may be disposed between the transfer transistors TX1 and TX4 at one side of the floating diffusion contact FD_CNT, and the boosting contact BT_CNT2 may be disposed between the transfer transistors TX2, and TX3 at the other side of the floating diffusion contact FD_CNT.

Whereas the boosting contacts BT_CNT1 and BT_CNT2 are formed to vertically overlap with the floating diffusion region FD, the boosting contacts BT_CNT1 and BT_CNT2 may not overlap with the transfer transistors TX1˜TX4. Although FIGS. 2 and 3 illustrate that the boosting contacts BT_CNT1 and BT_CNT2 are disposed at both sides of the floating diffusion contact FD_CNT, the scope or spirit of the disclosed technology is not limited thereto, and other implementations are also possible. For example, the boosting contact BT_CNT1 or BT_CNT2 can also be disposed only at one side of the floating diffusion contact FD_CNT as necessary.

The conductive line BT_ML1 formed to contact the boosting contact BT_CNT1 and the conductive line BT_ML2 formed to contact the boosting contact BT_ML2 may not vertically overlap with the transfer transistors TX1˜TX4. In addition, each of the conductive lines BT_ML1 and BT_ML2 may minimally overlap with the conductive line FD_ML in the horizontal direction.

As described above, the boosting contacts BT_CNT1 and BT_CNT2 may be spaced apart from the floating diffusion region FD by a predetermined distance and the insulation layer 120 exists between the floating diffusion region FD and the boosting contacts BT_CNT1 and BT_CNT2. Thus, the boosting contacts BT_CNT1 and BT_CNT2, the floating diffusion region FD, and the insulation layer 120 disposed between the floating diffusion region FD and each of the boosting contacts BT_CNT1 and BT_CNT2 may operate as a boosting capacitor BT_CAP. For example, each of the boosting contacts BT_CNT1 and BT_CNT2 may be used as an upper electrode of the boosting capacitor BT_CAP, and the floating diffusion region FD may be used as a lower electrode of the boosting capacitor BT_CAP.

In some implementations, the upper electrode of the boosting capacitor BT_CAP may be formed such that the upper electrode can vertically overlap with the floating diffusion region FD without vertically overlapping with the transfer transistors TX1˜TX4. In the implementations, such shape of the boosting contacts BT_CNT1 and BT_CNT2 is referred to as a contact shape. As described above, the boosting contacts BT_CNT1 and BT_CNT2 may overlap with the floating diffusion region FD without vertically overlapping with the transfer transistors TX1˜TX4. As a result, the boosting voltage generated by boosting of the floating diffusion region FD can minimally affect other elements, for example, transfer transistors TX1˜TX4. Thus, other elements such as the transfer transistors TX1˜TX4 can be less affected by the boosting voltage.

Each of the boosting contacts BT_CNT1 and BT_CNT2 is formed in a contact shape, and thus, a separation distance between the floating diffusion region FD and each of the boosting contacts BT_CNT1 and BT_CNT2 can be adjusted to be desirable one regardless of formation heights of the conductive lines BT_ML1, BT_ML2, and FD_ML. For example, when the boosting capacitor is formed using metal lines formed in the same layers as the conductive lines BT_ML1, BT_ML2, and FD_ML, if the separation distance between the floating diffusion region FD and the conductive lines becomes longer due to some reasons, the boosting effects may be relatively reduced. In this case, it may be considered to increase the boosting voltage to address the reduced boosting effects. However, if increasing the boosting voltage, there may occur unexpected problems since the increased boosting voltage can largely affect operational characteristics of other elements. In the present implementation of the disclosed technology, the upper electrode of the boosting capacitor is formed as a contact having the contact shape, the separation distance between the floating diffusion region FD and each of the boosting contacts BT_CNT1 and BT_CNT2 can be adjusted to be desirable one regardless of the formation heights of the conductive lines BT_ML1, BT_ML2, and FD_ML. Thus, the capacitance of the boosting capacitor BT_CAP can be easily adjusted. As a result, the floating diffusion region FD can be more efficiently boosted. For example, if the separation distance between the floating diffusion region FD and each of the boosting contacts BT_CNT1 and BT_CNT2 is minimized in length, the floating diffusion region FD can be easily boosted even when the boosting voltage is at a relatively low level.

In addition, the conductive lines BT_ML1 and BT_ML2 may be formed to vertically overlap with the floating diffusion region FD without vertically overlapping with the transfer transistors TX1˜TX4, such that the conductive lines BT_ML1 and BT_ML2 can allow the boosting voltage to minimally affect the transfer transistors TX1˜TX4. In addition, each of the conductive lines BT_ML1 and BT_ML2 may be formed to minimally overlap with the conductive line FD_ML in the horizontal direction, such that the conductive line FD_ML can be minimally affected by the boosting voltage.

In addition, although FIGS. 2 to 4 exemplarily illustrate that the bottom surface of each of the boosting contacts BT_CNT1 and BT_CNT2 is formed in a rectangular dot shape, the scope of the disclosed technology is not limited thereto, and the bottom surface of each of the boosting contacts BT_CNT1 and BT_CNT2 can also be formed in various shapes (or sizes) within the range of the floating diffusion region FD. Since the bottom surface (e.g., a width of the upper electrode of the boosting capacitor) of each boosting contact BT_CNT1 and BT_CNT2 is adjusted in size as described above, capacitance of the boosting capacitor can also be adjusted.

Although the above-mentioned embodiment of the disclosed technology has exemplarily disclosed that the boosting contacts BT_CNT1 and BT_CNT2 are formed in the unit pixel group (PXG) in which the unit pixels PX1˜PX4 share only one floating diffusion region FD for convenience of description, other implementations for providing the boosting contacts are also possible. For example, in a structure in which the floating diffusion region FD is independently formed for each unit pixel, the boosting contact may be formed not to vertically overlap with the transfer transistor and/or other pixel transistors (e.g., a reset transistor, a source follower transistor, and a selection transistor) while simultaneously vertically overlapping with the floating diffusion region FD.

In various implementations of the disclosed technology, an image sensing device may be structured to apply a boosting voltage to bias or boost a floating diffusion region FD to minimally affect operations of other peripheral elements.

In addition, the image sensing device based on some implementations of the disclosed technology can easily adjust capacitance of a boosting capacitor.

Those skilled in the art will appreciate that the embodiments may be carried out in other specific ways than those set forth herein. The above embodiments are therefore to be construed in all aspects as illustrative and not restrictive. In addition, those skilled in the art will understand that claims that are not explicitly cited in each other in the appended claims may be presented in combination as an embodiment or included as a new claim by a subsequent amendment after the application is filed.

Although a number of illustrative embodiments have been described, it should be understood that various modifications and enhancements of the disclosed embodiments and other embodiments can be devised based on what is described and/or illustrated in this patent document.

What is claimed is:

1. An image sensing device comprising:
at least one photoelectric conversion element configured to generate photocharges by performing photoelectric conversion of incident light;
a floating diffusion region adjacent to the at least one photoelectric conversion element and configured to receive and store the photocharges;
at least one transfer transistor electrically coupled to the at least one photoelectric conversion element and the floating diffusion region and configured to transmit the photocharges generated by the photoelectric conversion element to the floating diffusion region in response to a transmission signal; and
at least one boosting conductive material configured to receive a boosting voltage to boost the floating diffusion region and disposed in a region (1) that is vertically apart by a predetermined distance from the floating diffusion region and (2) vertically non-overlapping with the at least one transfer transistor.

2. The image sensing device according to claim 1, wherein the at least one transfer transistor includes:
a plurality of transfer transistors disposed adjacent to the floating diffusion region and spaced apart from each other by a predetermined distance.

3. The image sensing device according to claim 2, wherein:
the at least one boosting conductive material is disposed between the plurality of transfer transistors.

4. The image sensing device according to claim 1, wherein:
the boosting conductive material is disposed only in a region that vertically overlaps with the floating diffusion region.

5. The image sensing device according to claim 1, further comprising:
a floating diffusion contact formed over the floating diffusion region and coupled to the floating diffusion region; and
a first conductive line formed over the floating diffusion contact and coupled to the floating diffusion contact.

6. The image sensing device according to claim 5, wherein:
the boosting conductive material disposed in at least one side of the floating diffusion contact and vertically extends along a length of the floating diffusion contact.

7. The image sensing device according to claim 5, further comprising:
at least one second conductive line disposed in a same layer as the first conductive line, and configured to be coupled to the at least one boosting conductive material.

8. The image sensing device according to claim 7, wherein:
the at least one second conductive line is disposed over the floating diffusion region and vertically overlapping with the floating diffusion region without vertically overlapping with the at least one transfer transistor.

9. The image sensing device according to claim 7, wherein:
the at least one second conductive line is coupled to a boosting voltage node through which a boosting voltage is received.

10. The image sensing device according to claim 1, further comprising an insulation material that is disposed between the floating diffusion region and the at least one boosting conductive material.

11. An image sensing device comprising:
a pixel array of unit pixel groups, each unit pixel group including a plurality of unit pixels that generates an electrical signal in response to incident light through a photoelectric conversion of the incident light and shares a single floating diffusion region,
wherein each of the unit pixel groups includes:
a plurality of photoelectric conversion elements configured to generate photocharges by performing the photoelectric conversion of the incident light;
a plurality of transfer transistors configured to transmit the photocharges generated by the corresponding photoelectric conversion element to the floating diffusion region in response to a transmission signal; and
at least one boosting conductive material spaced apart from the floating diffusion region by a predetermined distance, and configured to vertically overlap with the floating diffusion region without vertically overlapping with the plurality of transfer transistors.

12. The image sensing device according to claim 11, wherein:
the plurality of unit pixels is arranged in a (2×2) structure, and disposed adjacent to the floating diffusion region.

13. The image sensing device according to claim 11, wherein:
the boosting conductive material is disposed only in a region that vertically overlaps with the floating diffusion region.

14. The image sensing device according to claim 11, wherein each of the unit pixel groups further comprises:
a floating diffusion contact formed over the floating diffusion region and coupled to the floating diffusion region; and
a first conductive line formed over the floating diffusion contact and coupled to the floating diffusion contact.

15. The image sensing device according to claim 14, wherein:
the boosting conductive material disposed in at least one side of the floating diffusion contact and vertically extending in parallel with the floating diffusion contact.

16. The image sensing device according to claim 14, wherein each of the unit pixel groups further comprises:
at least one second conductive line disposed in a same layer as the first conductive line, and configured to be coupled to the at least one boosting conductive material.

17. The image sensing device according to claim 16, wherein:
the at least one second conductive line is disposed over the floating diffusion region and vertically overlaps with the floating diffusion region without vertically overlapping with the plurality of transfer transistors.

18. The image sensing device according to claim 16, wherein:
the at least one second conductive line is coupled to a boosting voltage node through which a boosting voltage is received.

19. The image sensing device according to claim 11, wherein each of the unit pixel groups further includes an insulation material that is disposed between the floating diffusion region and the at least one boosting conductive material.
